(19) United States
(12) Patent Application Publication
(10) Pub. No.: US 2004/0179564 A1
(43) Pub. Date: Sep. 16, 2004

(54) Method for manufacturing an optical element having a structured surface, such optical element, and projection illumination system having such an optical element

(76) Inventors: Mandred Maul, Aalen (DE); Kirstin Antoni, Aalen (DE); Holger Kierey, Aalen (DE); Klaus Heidemann, Oberkochen (DE); Renate Winters, Heidenheim (DE)

Correspondence Address: ST. ONGE STEWARD JOHNSTON & REENS, LLC, 986 BEDFORD STREET, STAMFORD, CT, 06905-5619, US

(21) Appl. No.: 10/744,802

(22) Filed: Dec. 23, 2003

(30) Foreign Application Priority Data
Dec. 23, 2002 (DE) 102 60 819.9

(51) Int. Cl. H01S 5/00

(52) U.S. Cl. 372/43

(57) ABSTRACT

A method for manufacturing an optical element having at least one surface with an optically effective structure, from a substrate, is described, wherein the substrate is provided, an auxiliary layer is applied onto the substrate, a surface structure is formed on a surface of the auxiliary layer, and the auxiliary layer is ion beam etched such that the surface structure of the auxiliary layer is transferred to the substrate in order to obtain the optically effective structure of the optical element.

### CROSS-REFERENCE TO RELATED APPLICATIONS

The present application claims priority of German patent application 102 60 819.9 filed on Dec. 23, 2002.

### BACKGROUND OF THE INVENTION

The present invention relates to a method for manufacturing an optical element having at least one surface with an optically effective structure, from a substrate, and, in particular, relates to optical elements for use in projection illumination systems, in particular projection illumination systems for use in semiconductor lithography equipment.

Such optical elements may be, in the scope of the present invention, refractive optical elements, like lenses, prisms, and so on, having an optically effective structure on at least one of their surfaces, diffractive optical elements like diffraction gratings which can be used in reflection or in transmission, or scattering disks. In case of diffraction gratings the optically effective structure can be a profile in form of a saw tooth structure, for example. In case of a scattering disk, the optically effective structure can be a roughened surface suitable for scattering light impinging on the scattering disk.

In the manufacturing of micro-optical elements, for example refractive optical elements, diffractive optical elements, scattering disks, gratings or the like several mechanical and lithographic processes have been used for producing an optically effective structure on the surface or surfaces of these elements. Such lithographic processes are, for example, photo-lithography, electron-beam lithography, ion-beam lithography, holography, laser ablation lithography etc.

Lithographic processes often require several steps of exposure and chemical etching operations in order to obtain the desired optical elements with the desired structured surface.

Mechanical processes are mechanical ruling, single point diamond turning or, in case of scattering disks, mechanical grinding.

All such methods require an extreme preciseness of the manufacturing apparatus and tools. As a result, such manufacturing methods for the optically effective surface are expensive and costly. In order to reduce costs, optical gratings are often manufactured as copies of a master grating which has been previously manufactured by mechanically ruling or by holographic recording as mentioned before, wherein said copies are manufactured by replication from the master element.

In general, the relative small structures of diffractive optical elements are, as already mentioned, frequently produced by photo-lithography, in which method a photosensitive resist is applied onto a substrate, and the photosensitive resist is exposed to an image of the desired surface structure and subsequently chemically etched. Usually several steps of etching are used to optimize the diffracting effect of the profile shape of the structured surface.

In case of a so-called 8-step-diffracting optical element the exposure step has to be carried out three times, wherein in each single exposure step the substrate has to be very precisely re-positioned. Manufacturing of very small diffracting structures requires a lithographic equipment having a very good performance (small minimum feature sizes, high alignment preciseness), which necessitates expensive machines and apparatus so that the production of a small number of optical elements is unprofitable.

Mechanical and lithographical techniques are, therefore, only suitable for manufacturing single optical elements. If a larger number of optical elements is needed, it is common to multiply the costly manufactured optical master element by replication techniques.

Common replication techniques which are widely used, are replication in epoxy resin, injection molding and hot embossing. Injection molding is suitable for a large number of items only, because an expensive injection mold has to be manufactured. The transfer of the diffracting structure to the optical element to be manufactured is not very precise. If the final optical element is to be used in transmission, one depends on the spectral transmission characteristics of the used replication compounds, which are mostly thermoplasts. In particular, there are no materials with good transmission in the ultraviolet spectrum of light, in particular in the DUV and VUV range. Furthermore, thermal problems arise when the optical elements manufactured in this manner are subject to high optical intensities or power, which can lead to a damage of the optical elements.

In the method of epoxy resin replication, a separation layer is applied onto the master element. A small amount of a liquid replication resin is applied, and a copy substrate is laid onto the resin. After curing the resin, the master element and the copy are separated. The result is a negative copy of the master element. If the negative copy is copied again, the second copy is a positive copy of the original master element. While the quality of transfer of the diffracting structures is very good, the same restrictions exist as in the case of injection molding when the optical element is used in transmission, because the optical characteristics of the replication resins are limited with respect to the usable spectral range and the optical power.

In the method of hot-embossing, it is necessary to manufacture an expensive stamp which is pressed in a thin layer of a thermoplast on a copy substrate under high pressure and at elevated temperatures. This method has the drawback to require a cost extensive stamp which, furthermore, is subject to wear in short time due to the harsh process conditions of this method.

In the known methods for manufacturing scattering disks the surface of a substrate, for example fused silica, is roughened by reactive chemically etching the ground surface such that the light passing through the scattering disk or impinging the scattering disk is scattered. A disadvantage is that the scattering angle distribution cannot be reproduced in reliable manner with this kind of manufacturing technique, but is the result of a random creation process during chemically etching the surface.

Furthermore, the conventional manufacturing methods are not suited to manufacture optical elements having at least one surface with an optically effective structure from fluoride crystals as the substrate, in particular from calcium fluoride (CaF₂). For example, such materials of such compounds are needed for optical elements for use at a wavelength of e.g. 157 nm or even shorter wavelengths, since fused silica as well as plastics are damaged rapidly at these wavelengths due to their very high absorption of light. Further, the conventional methods are not suited in order to manufacture scattering disks from calcium fluoride. When etching calcium fluoride by means of reactive etching no sufficiently homogenous distribution of the scattering angles is obtained.

Document WO 02/071150 A2 discloses a method for manufacturing a device using a lithographic template, wherein a substrate is provided, the substrate is coated with a photocurable liquid, the lithographic template is positioned in contact with the photocurable liquid, a pressure is applied to the template so that a pattern is created in the photocurable liquid, and subsequently radiation is transmitted through the lithographic template to expose at least a portion of the photocurable material on the substrate, thereby further affecting the pattern in the photocurable liquid, and the template is removed from the substrate. The device to be manufactured is a semiconductor device.

### SUMMARY OF THE INVENTION

It is an object of the present invention to provide a method for manufacturing an optical element having at least one surface with an optically effective structure, from a substrate, which is cost saving even in case that only a small number of identical optical elements is to be manufactured.

It is another object of the present invention to provide a method for manufacturing an optical element having a surface with an optically effective structure, from a substrate, which makes it possible to manufacture the optical element from such substrates which have as good optical characteristics as possible in dependence on their specific application and use, i.e. all advantages of the material of the substrate can be used for the manufactured optical element.

According to a first aspect of the present invention, a method for manufacturing an optical element having at least one surface with an optically effective structure, from a substrate, is provided, comprising the steps of: providing said substrate, applying an auxiliary layer onto said substrate, forming a surface structure on a surface of said auxiliary layer of material, and ion beam etching said auxiliary layer such that said surface structure of said auxiliary layer is transferred to said substrate in order to obtain said optically effective structure of said optical element.

According to another aspect of the present invention a method for manufacturing an optical element having at least one surface with an optically effective structure, from a substrate, is provided comprising the steps of: providing said substrate, applying a thin auxiliary layer onto said substrate by applying a curable material in liquid state onto said substrate, forming a surface structure on a surface of said auxiliary layer of material by providing a master element having a surface comprising said surface structure in inverted form, pressing said master element onto said curable material so as to form said surface structure in said liquid curable material, curing said curable material, and separating said master element from said curable material after having been cured; and removing said auxiliary layer by ion etching said auxiliary layer such that said surface structure of said auxiliary layer is transferred to said substrate.

It is another object of the present invention to provide an optical element manufactured according to the method mentioned before.

It is another object of the present invention to provide a projection illumination system comprising an optical element of the aforementioned kind.

### BRIEF DESCRIPTION OF THE DRAWINGS

The foregoing and further and more specific objects and advantages of the present invention will become readily apparent to those skilled in the art from the following detailed description of preferred embodiments thereof taken in conjunction with the drawings, in which:

FIG. 1 shows a schematic representation of a projection illumination system for use in micro-lithography which is usable for projecting structures onto wafers;

FIGS. 2a-2e show a method according to an aspect of the invention, wherein the surface structure of the auxiliary layer is produced by means of a replication technique using a master element which is pressed into the auxiliary layer prior to curing same;

FIGS. 3a-3e show a method according to the invention for manufacturing an optical element having a structured surface, wherein the auxiliary layer is formed by a fused silica disk provided with a surface structure;

FIGS. 3a-4e show a method according to the invention for manufacturing an optical element having a structured surface, wherein the auxiliary layer is formed by a curable plastic provided with a surface structure;

FIGS. 5a-5c show a method according to the invention for manufacturing a scattering disk from calcium fluoride, wherein the auxiliary layer is formed by a photosensitive resist, and a speckle pattern having a suitable intensity distribution is illuminated into the photosensitive resist in order to produce the desired surface structure of the auxiliary layer;

FIG. 6 shows a schematic representation of a lithographical manufacturing process for manufacturing an 8-step-diffracting optical element according to the prior art;

FIGS. 7a-7f show another exemplary embodiment of a method for manufacturing an optical component having a surface with an optically effective structure, from a substrate;

FIG. 8 is a diagram showing a removal or etching rate of ion beam etching an epoxy resin layer in comparison with a removal rate of ion beam etching a fused silica substrate in dependence of an ion incidence angle, wherein argon is used as etching gas;

FIG. 9 is a diagram showing a process simulation of ion beam etching of an 8-step-diffractive optical element, wherein fused silica has been used as substrate; and

FIG. 10 is a diagram showing a process simulation of ion beam etching of a blaze grating in fused silica as substrate.

### DETAILED DESCRIPTION OF PREFERRED EXAMPLARY EMBODIMENTS

The present invention provides a simple and cost-saving method for manufacturing optical elements having a surface with an optically effective structure. In particular, the optical elements manufactured according to the present invention are suited for use at wavelengths of smaller than 250 nm and even smaller than or equal to 157 nm, if required. In preferred embodiments, the optical elements, in particular diffracting optical elements, refracting optical elements or scattering disks are manufactured from fluoride crystals, in particular from alkaline earth fluoride compounds, in particular from calcium fluoride. As will be described in more detail later, an auxiliary layer is applied onto the substrate which preferably comprises an alkaline earth fluoride compound, in particular calcium fluoride, and the auxiliary layer is provided with the desired surface structure by means of a suited process.

However, the invention is not restricted to optical elements for use at wavelengths smaller than or equal to 157 nm or to optical elements made of calcium fluoride.

The compound consisting of the structured auxiliary layer and the substrate is subsequently etched by means of non-reactive ion beam etching which uniformly removes the materials of the auxiliary layer and the substrate in order to transfer the structure or relief of the auxiliary layer into the substrate. In this way, the auxiliary layer can be provided with the respective surface structure by means of conventional and long-proved methods in a simple and advantageous manner, whereafter in preferably one non-reactive etching step the surface profile is transferred into the alkaline earth fluoride substrate. In this way, it is possible to transfer arbitrary surface profiles. It is possible to transfer 8-step-profiles of a diffractive optical element in only one etching step, wherein only the preciseness of the surface structure in the auxiliary layer is important. Thereby, the optical performance of the manufactured optical elements can be significantly improved. In the same way saw tooth profiles, for example, can be transferred, whereby the efficiency of the diffractive optics is increased in the same way. Furthermore, the method according to the invention also renders possible the transfer of refractive surface profiles with significantly better reproducibility than it is possible with mechanical manufacturing processes.

Furthermore, the method according to the invention makes it possible to manufacture scattering disks from calcium fluoride which was not possible with conventional manufacturing methods.

In preferred embodiments of the invention, the auxiliary layer can be formed from a curable material, and the surface structure of the auxiliary layer is produced by means of a master element which is pressed on the auxiliary layer before the latter is cured.

By this measure the manufacturing process can be significantly simplified, because the preciseness of structuring is only necessary when manufacturing the optical master element. The master element is then used as a stamp for generating the surface structure of the auxiliary layer. The need of expensive lithographical equipment for a line production can be dropped which equipment is economically efficient only when large numbers of identical optical elements are manufactured.

Further, it can be preferred if the auxiliary layer is formed from a material which can be structured in a reproducible manner by means of reactive etching. This makes it possible to manufacture the surface structure of the auxiliary layer with known, conventional and precise techniques (for example by lithographic techniques), wherein the surface structure of the auxiliary layer can be subsequently transferred in unaltered or approximately unaltered fashion to the substrate in only one single step.

Further, it is preferred within the scope of the invention when the transfer of the surface structure of the auxiliary layer to the substrate by means of non-reactive ion beam etching is carried out only when the auxiliary layer has been removed by means of reactive ion etching (without altering the surface structure) so far that the deepest site of the auxiliary layer has reached approximately the substrate. The advantage is that only the last step of the transfer of the surface structure to the substrate is carried out by means of non-reactive ion beam etching which is slower than reactive etching which acts quicker and ensures a better maintaining of edges of the profile of the structured surface.

In case the optical element to be manufactured is a scattering disk, it is preferred if the auxiliary layer is formed by a photosensitive resist, and a speckle pattern is produced which has a suitable intensity distribution and is imaged into the photosensitive resist, whereafter the photosensitive resist is developed. This measure is in particular suited for manufacturing scattering disks having an optimal scattering angle distribution which, further, is reproducible with respect to their statistic characteristics. By virtue of the present invention, the generation of the scattering angle distribution is no longer the result of a random creation process during the chemical etching of a substrate surface.

Now, with respect to the drawings further details of the invention are described.

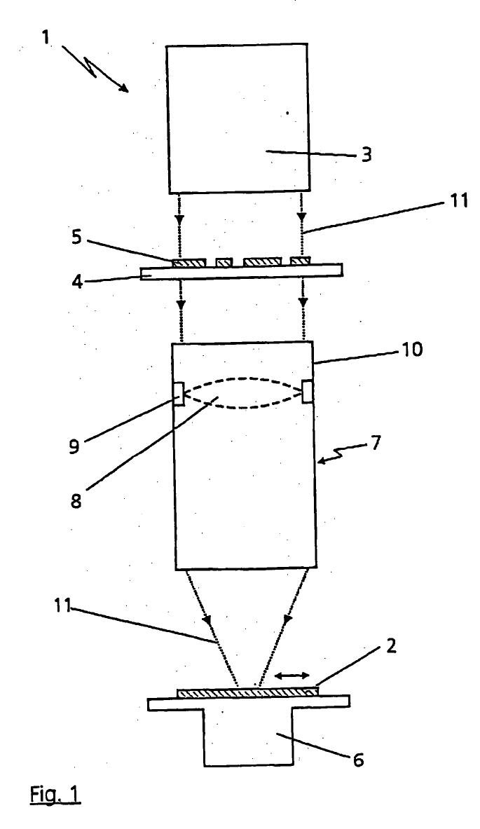

FIG. 1 shows a projection illumination system 1 for use in micro-lithography. The projection illumination system 1 is used for illuminating structures onto a substrate which is covered with a photosensitive material. In general, the substrate consists of silicon and is commonly referred to as wafer 2, which is used for manufacturing semiconductor components, for example computer chips.

In general, the projection illuminating system 1 substantially comprises an illuminating device 3, a device 4 for receiving and precisely positioning a mask having a grid-like structure, which mask is referred to as reticule 5, by means of which the structures to be imaged on the wafer 2 are determined, a device 6 for supporting, moving and precisely positioning the wafer 2 and an imaging device, namely a projection lens 7 having several optical elements, for example lenses 8, which are supported by means of mounts 9 in a lens housing 10 of the projection lens 7.

The basic principle of function provides that the structures formed in the reticule 5 are illuminated or imaged onto the wafer 2 with reduction in size of the structures.

After the wafer 2 has been exposed, the wafer 2 is moved in the direction of an arrow shown in FIG. 1, so that a plurality of individual areas on the same wafer 2 are illuminated in succession with the structure determined by the reticule 5, respectively. Due to the stepwise forward movement of the wafer 2 in the projection illuminating system 1, the latter is often referred to as stepper.

The illuminating device 3 provides for a projection beam 11, for example light or a similar electromagnetic radiation, which is needed for the imaging of the reticule 5 on the wafer 2. A laser or the like can be used as source for the afore-mentioned radiation. The radiation is shaped in the illuminating device 3 by means of optical elements such that the projection beam 11 has the desired characteristics with respect to diameter, polarization, shape of the wave front and the like when impinging on the reticule 5.

An image of the reticule 5 is produced through the projection beam 11 and transferred to the wafer 2 by the projection lens 7 in a reduced size, accordingly, as already described above. The projection lens comprises a plurality of individual refractive and/or reflective optical elements, like lenses, mirrors, prisms and the like.

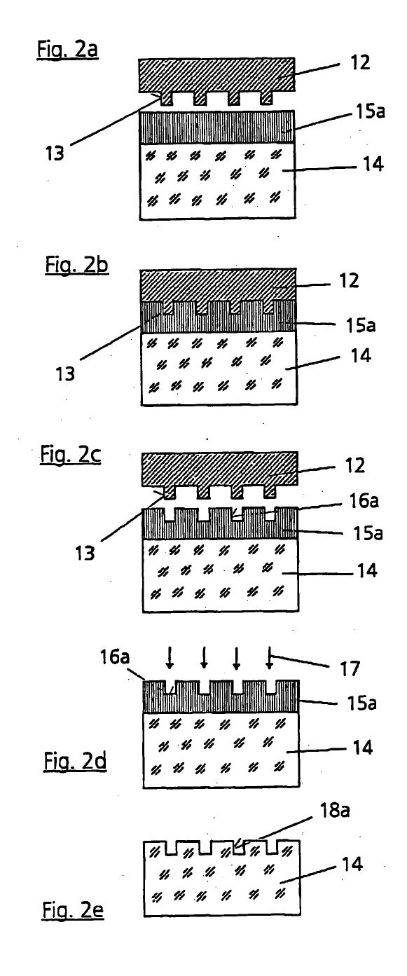

In the illuminating system 3, in which the light source is arranged, microstructured diffractive optical elements, like gratings, scattering disks and the like are arranged in a predetermined manner. FIGS. 2 through 5 show methods for manufacturing such microstructured optical elements, in particular such optical elements made of calcium fluoride substrate. In the figures, the auxiliary layers are shown with highly exaggerated thicknesses/dimensions for the sake of a better understanding only.

FIG. 2a shows a mirror-inverted secondary master element 12 copied from a primary master element (not shown), wherein the primary master element incorporates a complete three-dimensional information of the optical element to be manufactured, in the present case a surface structure 13 of a binary diffractive optical element to be manufactured. The primary master element has been manufactured by E-beam-lithography, for example. In another embodiment the primary master element can be manufactured by means of other micro-lithographic techniques or other suitable methods. In another embodiment, the primary master element can contain the three-dimensional information of another microstructured optical element to be manufactured, for example a step profile of an 8-step-diffracting optical element or a continuous surface relief of a refractive optical element or of a scattering disk, for example. The mirror-inverted secondary master element 12 can be used for manufacturing a plurality of microstructured optical elements of the same type so that only the preciseness of the surface structure of the secondary master element is important for the preciseness of the optical elements to be manufactured. Thus, a significantly better reproducibility of the respective surface structures is achieved.

By replicating the secondary master element or a replication stamp 12 from the primary master element the desired surface structure 13 of the microstructured optical element to be manufactured is transferred to the mirror-inverted secondary master element 12.

FIG. 2a further shows a calcium fluoride substrate 14, which forms the basis for the microstructured optical element to be manufactured. A calcium fluoride substrate 14 is coated with a thin film 15a (thickness<0.1 mm) for replicating the stamp surface 13 of the replication stamp 12, wherein the film 15a is of a material suited for replication purposes. In the present embodiment, the film 15a is made from epoxy resin and comprises a thickness of about 500 nm.

As depicted in FIG. 2b, the mirror-inverted secondary master element 12 is pressed into the film 15a of epoxy resin, which is not yet cured. Thus, a direct image 16a of the surface structure 13 to be manufactured is created on the film 15a after the epoxy resin is cured, as shown in FIG. 2c.

The surface structure or the relief 16a of the. epoxy resin film 15 (auxiliary layer) is subsequently transferred to the calcium fluoride substrate 14 by means of non-reactive ion beam etching the compound consisting of the relief 16a and the calcium fluoride substrate 14. It is important that the etching uniformly removes the epoxy resin film 15a and the calcium fluoride substrate 14.

In another embodiment the etching can also be carried out in form of another etching process which removes the epoxy resin film until the deepest site of the structured film 15a has approximately reached the calcium fluoride substrate 14, whereafter etching is further carried out in form of non-reactive ion beam etching.

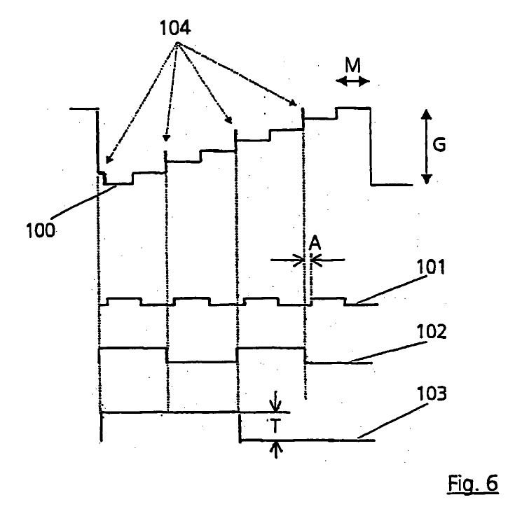

As FIG. 2e shows, the surface structure 13a of the primary master element (not shown) or the mirror-inverted secondary master element 12 has been completely transferred to the calcium fluoride substrate 14 in unaltered fashion as surface structure 18a of the calcium fluoride substrate 14. Now the manufacturing of the microstructured diffractive optical element in calcium fluoride is finished. In this context it is in particular advantageous that the surface structure of the primary master element or the mirror-inverted secondary master element 12 which can be produced by means of conventional methods, can be transferred to the calcium fluoride substrate 14 by a single etching step only, after said surface structure has been replicated to the film 15a. In case of a so-called 8-step-diffracting optical element, this method saves exposing and etching steps which, in conventional methods, have to be carried out three times in succession, wherein in each single step the substrate has to be re-positioned in a very precise manner (alignment precision). Such a conventional lithographic manufacturing method is illustrated in FIG. 6 schematically. In order to obtain a step profile 100 of the 8-step-diffracting optical element. with an overall etching depth D with a phase-delay of ⅞ of the light wavelength and a minimal feature size M three exposing and etching steps are carried out by means of binary masks 101, 102 and 103 with etching depths T, wherein the mask 101 generates a delay of ⅛ of the light wavelength, the mask 102 a delay of 2/8 of the wavelength and the mask 103 a delay of 4/8 of the light wavelength. Alignment errors A are created by an imprecise positioning of the single masks 101, 102, 103 in the single exposure steps and cause errors 104, in particular at the edges of the resulting step-profile 100.

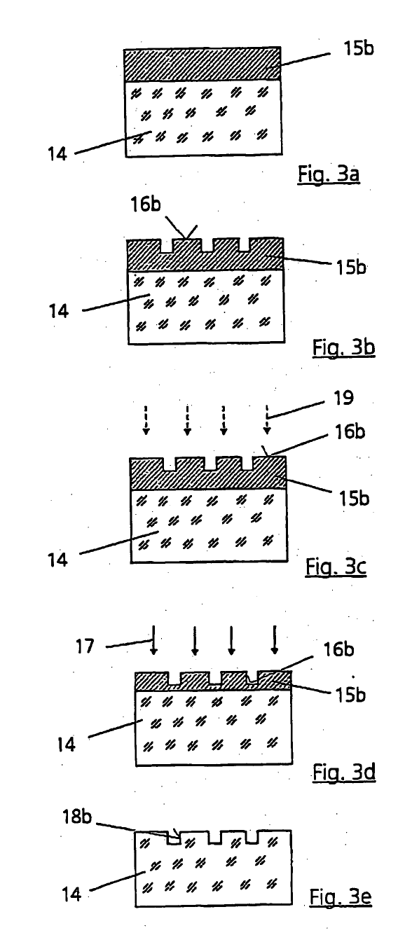

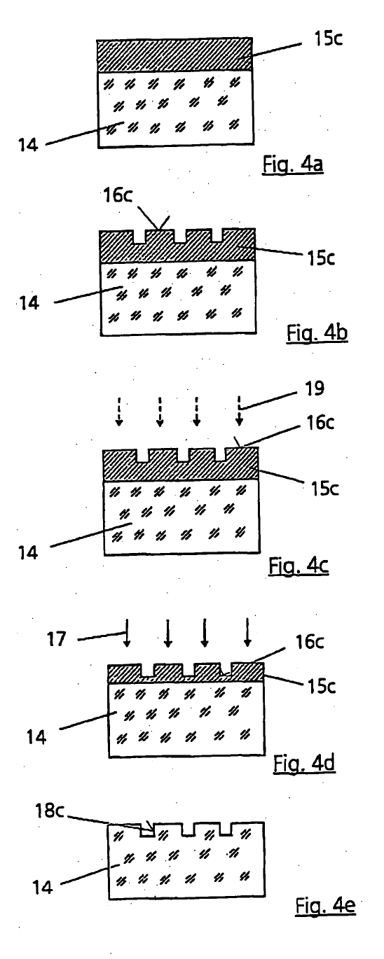

In FIGS. 3a through 3e the method according to the invention is used for manufacturing a scattering disk from calcium fluoride (CaF₂). To this end, a fused silica disk 15a is applied on the calcium fluoride substrate 14 by means of optically bonding.

In FIG. 3b, the surface structure 16b of the fused silica disk 15b has been produced by statistical roughening the surface of the fused silica disk 15b by means of grinding and wet-chemical etching. In more detail, the following steps are carried out. First, material is removed from the fused silica disk 15b, whereafter the surface of the fused silica disk 15b is roughened by lapping using suitable abrasives, and whereafter a surface of the fused silica disk 15b is flattened or smoothed by wet-chemical etching using sulphuric or hydrofluoric acid. The scattering angle of the scattering disk to be manufactured can be adjusted via the duration of etching in this case.

As FIG. 3c shows, the thickness of the fused silica disk 15b can be reduced by means of further reactive etching processes (in FIG. 3c represented by arrows in broken lines) which do not alter the surface structure 16b of the fused silica disk 15b, until the deepest site of the fused silica disk 15b has approximately approached the calcium fluoride substrate 14, and, thus, only a relative short-time ion beam etching is necessary (in FIG. 3c represented by arrows 17).

In FIG. 3e, the surface structure 16b of the fused silica disk 15b as the auxiliary layer has now been transferred to the surface structure 18b of the calcium fluoride substrate 14 by means of ion beam etching 17 (FIG. 3d).

FIGS. 4a through 4e sketch a further method for manufacturing a scattering disk from a calcium fluoride substrate 14.

In FIG. 4a, a curable plastic layer 15c as the auxiliary layer has been applied on the calcium fluoride substrate 12 by means of spin-on depositing.

As FIG. 4b shows, a surface structure 16c is applied to the curable plastic layer 15c. This is achieved by roughening the surface of the plastic layer 15c by means of lapping using suitable abrasives after the plastic 15c is cured. The surface of the plastic layer 15c is subsequently flattened or smoothed by means of diluted solvents. As FIG. 4c shows, the thickness of the plastic layer 15c can be further reduced by means of reactive etching processes which do not alter the surface structure 16c of the plastic layer 15c (in FIG. 4c indicated as arrows 19 in broken lines), until the deepest site of the plastic layer 15c has at least approximately approached the calcium fluoride substrate 14, in order to render possible an ion beam etching step (in FIG. 4d indicated as arrows 17) as short as possible for transferring the surface structure 16c of the plastic layer 15c to the calcium fluoride substrate 14.

FIG. 4e shows that the surface structure 16c of the plastic layer 15c has been transferred to the calcium fluoride substrate 14 as surface structure 18c of the calcium fluoride substrate 14. The scattering disk, thus, is completed.

It goes without saying that the methods represented in FIGS. 3a through 3e and 4a through 4e are not only suited for manufacturing scattering disks, but also to make other microstructured optical elements, wherein only the method steps described with respect to FIGS. 3b and 4b for creating the surface structures 16b and 16c in the auxiliary layer could be replaced by corresponding lithographic, holographic or mechanical techniques etc.

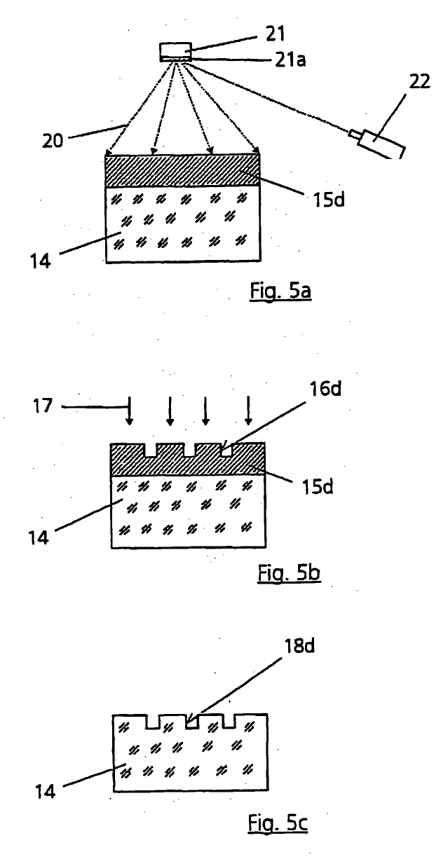

FIGS. 5a through 5c describe another embodiment of the method according to the invention for making a scattering disk from a calcium fluoride substrate 14 using a speckle pattern which is illuminated into a photosensitive resist.

In another embodiment glass, plastic or fused silica could be used as the substrate.

As emerges from FIG. 5a, the calcium fluoride substrate 14 is provided with a photosensitive resist layer 15d as the auxiliary layer. By coherent illumination (in FIG. 5a represented by arrows 20 in broken lines) of a diffuser 21 having a rough surface 21a by means of a laser 22 the calcium fluoride substrate 14 is exposed to a speckle pattern (not shown). The photosensitive resist layer 15d is subsequently developed, whereafter the latter comprises a surface structure 16d (FIG. 5b).

As further shown in FIG. 5b, the surface structure 16d of the photoresist layer 15d is transferred by means of ion beam etching (in FIG. 5b indicated by dashed lines 17) into the calcium fluoride substrate 14, wherein the surface structure 18d of the calcium fluoride substrate 14 is created as an exact copy of the surface structure 16d of the photosensitive resist layer 15d.

The present concept for manufacturing scattering disks makes use of the statistical properties of speckle patterns: It applies to a speckle pattern which is created in a distance z from a diffuser 21 which is sufficiently rough and fine structured and coherently illuminated that its spectral intensity power density substantially is the autocorrelation function of the illumination intensity distribution I (x, y) on the diffuser (reference is made to Goodman “Statistical Properties of Laser Specal”, page 35 ff., ed. J. T. Dainty, Springer 1975): PSD_{I} (fₓ, f_{y})=δ(fₓ, f_{y})+AC {I(x, y)}.

The δ-function at the frequency 0 results from the positive average of the intensity distribution as this generally applies to the zeroth order of amplitude gratings. If the intensity profile of the specal pattern is transferred into a phase profile of suited modulation depths, the zeroth order disappears.

Accordingly, scattering disks having a well-defined scattering distribution which is not necessarily a Gauss distribution can be manufactured according to the method represented in FIG. 5. A method for manufacturing scattering disks has been created having the advantage of a high reproducibility of the scattering angle distribution.

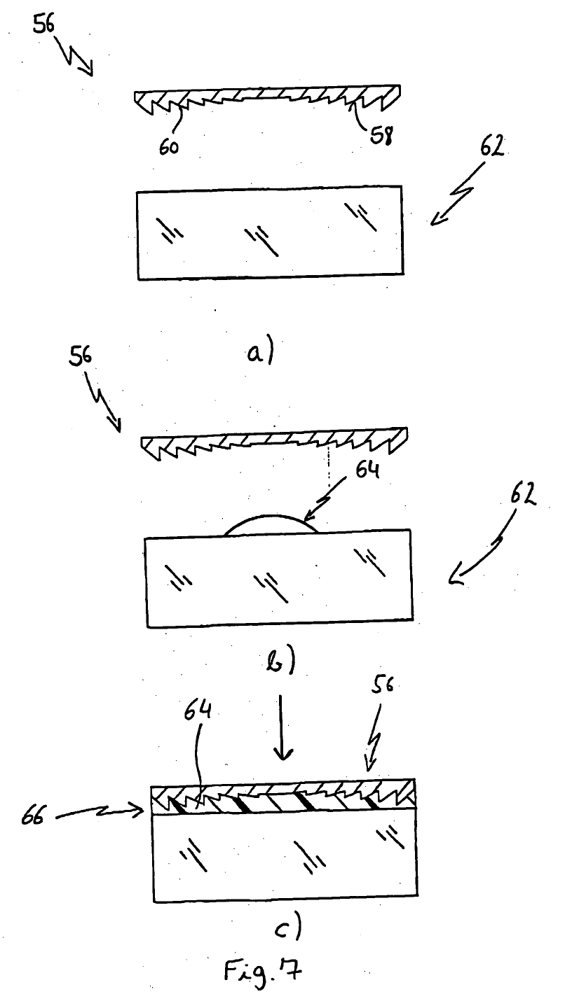

FIGS. 7a through f show another exemplary embodiment of a method for manufacturing an optical element 50 (shown in FIG. 7f). Optical element 50 has a surface 52 with an optically effective structure 54 which is, in the present exemplary case, configured as a saw tooth profile so that optical element 50 can be used as diffraction grating.

Optical element 50 is, for example, a diffractive optical element which is used in transmission, i.e. is transparent, and may, for example, also be used in the projection illuminating system 1 of FIG. 1.

In the following, a method for manufacturing optical element 50 is described in more detail.

With respect to FIG. 7a), a master element 56 is provided which has a surface 58 comprising a surface structure 60, which is a negative copy of the surface structure 54 of optical element 50 to be manufactured.

In general, master element 56 can be manufactured in different ways. For example, surface structure 60 of surface 58 of master element 56 can be created by means of holographic recording in photosensitive resist, followed by etching steps if necessary; by means of a mechanical partition in a ductile layer, for example gold, followed by etching steps if necessary; by diamond cutting in glass, plastic or metal; by means of a gray scale illumination in a laser or electron beam illuminator, by which method the profile shape of the diffractive structure is directly written by dose controlling so as to obtain a diffractive element in the resist; by a lithographic mask technique.

It is preferred if the master element 56 is coated with a hard protection layer, for example SiO₂ or the like. It is further preferred if at least surface 58 of master element 56 is provided with an anti-adhesive layer, for example a fluoropolymer, silicone etc.

When a protection layer or an anti-adhesive layer is deposited on surface 58 of master element 56, care should be taken that surface structure 60 of master element 56 is not altered, in particular not rounded. Therefore, protection and anti-adhesive layers must be as thin as possible in order not to alter the profile form of surface structure 60.

Further with respect to FIG. 7a) a substrate 62 is provided from which optical component 50 of FIG. 7f) is to be manufactured, i.e. substrate 62 forms a body 64 of the later finished optical component 50.

Depending on the intended purpose of optical component 50 to be manufactured and the desired properties of optical component 50, substrate 62 can be chosen from a great variety of materials.

For example, substrate 62 is chosen from the group comprising materials transparent to light in a predetermined wavelength range, which materials can comprise glasses, fused silica, silicon, germanium, silicon carbide, calcium fluoride, magnesium fluoride, zinc selenide or others. Calcium fluoride as material for substrate 62, for example, is chosen in case that optical element 50 is intended for use in projection illuminating system 1 for a wavelength of 157 nm (or less) for use in semiconductor lithography.

Additionally or alternatively, substrate 62 can be chosen from the group of materials which are reflective to light in a predetermined wavelength range, which materials may be for example silver, gold, aluminum, ruthenium. Further, substrate 62 can be chosen from the group of materials, comprising heat conducting materials like aluminum and silver. Other desired properties of substrate 52 can be a high mechanical hardness and a high resistance to wear etc.

In the next step (FIG. 7b), a curable material 64 in liquid state is supplied onto substrate 62 in order to form an auxiliary layer 66 from said curable material 64 (FIG. 7c)) on substrate 62.

Curable material 64 preferably is an epoxy resin having a viscosity lower than 150 mm²/s, more preferably lower than 100 mm²/s at room temperature.

In a subsequent step, master element 56 is pressed on said curable material 64 so as to form the surface structure 60 of surface 58 of master element 56 in the liquid curable material 64, prior to curing curable material 64.

Master element 56 is pressed onto curable material 64, in order to form the auxiliary layer 66 having the surface structure 60, with a pressure in a range of about 0.1 to 5 bar, which is a low pressure when compared with the pressure required for the conventional method of hot-embossing.

Pressing master element 56 onto curable material 64 is carried out such that the remaining unaltered part without a surface structure of the auxiliary layer 66 has a very small thickness, preferably in the range of about 10 to about 1000 nm.

After master element 56 has been pressed onto curable material 64 in order to form auxiliary layer 66, curable material 64 is cured, preferably thermically cured. Thermically curing has the advantage that the applied heat initially additionally lowers the viscosity of the curable material 64 whereby the remaining thickness of auxiliary layer 66 is further reduced in size.

After curable material 64 has been cured to form auxiliary layer 66 in FIG. 7c) master element 56 is separated from curable material 64 (indicated by an arrow 68 in FIG. 7d)). Now, surface structure 60 of master element 56 has been replicated into auxiliary layer 66 to form a surface structure 54′ which is identical or approximately identical with surface structure 54 of optical element 50 to be manufactured (FIG. 7f)).

In the next step (FIG. 7e) auxiliary layer 66 which in the preferred embodiment consists of cured epoxy resin, is removed by ion beam etching auxiliary layer 66 such that surface structure 54′ is transferred to substrate 62 until the optically effective structure 54 of optical element 50 to be manufactured is obtained.

Ion beam etching auxiliary layer 66 in order to transfer surface structure 54′ to substrate 62 is accomplished in the preferred embodiment by shape-maintaining ion beam etching, reactive ion beam etching, reactive ion etching or combinations thereof. In FIG. 7e) ions are illustrated by circles (reference numeral 70) which are directed toward surface 65 of auxiliary layer 66 according to arrows 72 at an incident angle ψ (FIG. 7e)).

Since auxiliary layer 66 and substrate 62 usually differ with respect to their constituting materials, the etching or removal rate of auxiliary layer 66 differs from the etching or removal rate of substrate 62. Furthermore, the ion etching rate depends on the ion incidence angle ψ and on the used gas mixture for producing the ions.

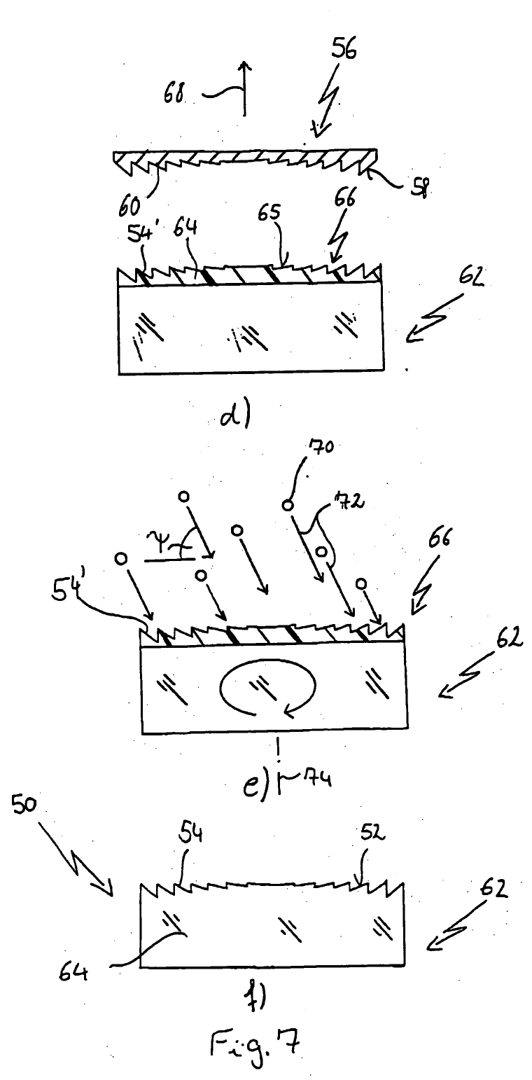

In FIG. 8, the ion etching rate v is depicted for epoxy resin (etching rate v₁, auxiliary layer 66) and for fused silica (etching rate v₂, substrate 62) as a function of the ion incident angle ψ. Pure argon gas has been used as the etching gas.

A course adjustment of the ratio between the etching rates for auxiliary layer 66 and for substrate 62 is achieved by matching the etching rate curves (in dependence on the ion incidence angle ψ) of auxiliary layer 66 and substrate 62 to one another by a suitable admixing of reactive gases (for example O₂ or CF₄) to the argon gas flux in the ion source. For example, O₂ increases the etching rate of organic layers as it is the case for auxiliary layer 66 (epoxy resin), and CF₄ increases the etching rate of materials like glass, fused silica, zerodur and silicon, which are possible materials for substrate 62.

The dependence of the etching rate v on the ion incidence angle ψ can also be altered by altering the gas mixture. A cosinoidal dependence of the etching rate on the ion incidence angle is most suited for the transfer of surface structure 54′ to substrate 62 in order to obtain surface structure 54. By admixing reactive gas components to argon the maximum of the etching rate is shifted to smaller angles.

In this way, the etching process can be controlled in an optimum manner so that the surface structure 54′ is transferred to substrate 62 in unaltered or at least approximately unaltered fashion, which can be accomplished by controlling the etching rate for auxiliary layer 66 with respect to the etching rate for substrate 62.

A fine adjustment of the etching process uses the different ion incidence angle dependencies of the etching rate v₁ of epoxy resin and v₂ of substrate 62 and is accomplished by choosing a suitable ion incidence angle ψ₀, for which the ratio of the etching rates v₂ (ψ₀)/v₁ (ψ₀) is such that the transfer of the surface structure 54′ from auxiliary layer 66 to surface structure 54 of substrate 62 is as linear as possible and ensures preservation of steep edges and sharp contours of the profile shape.

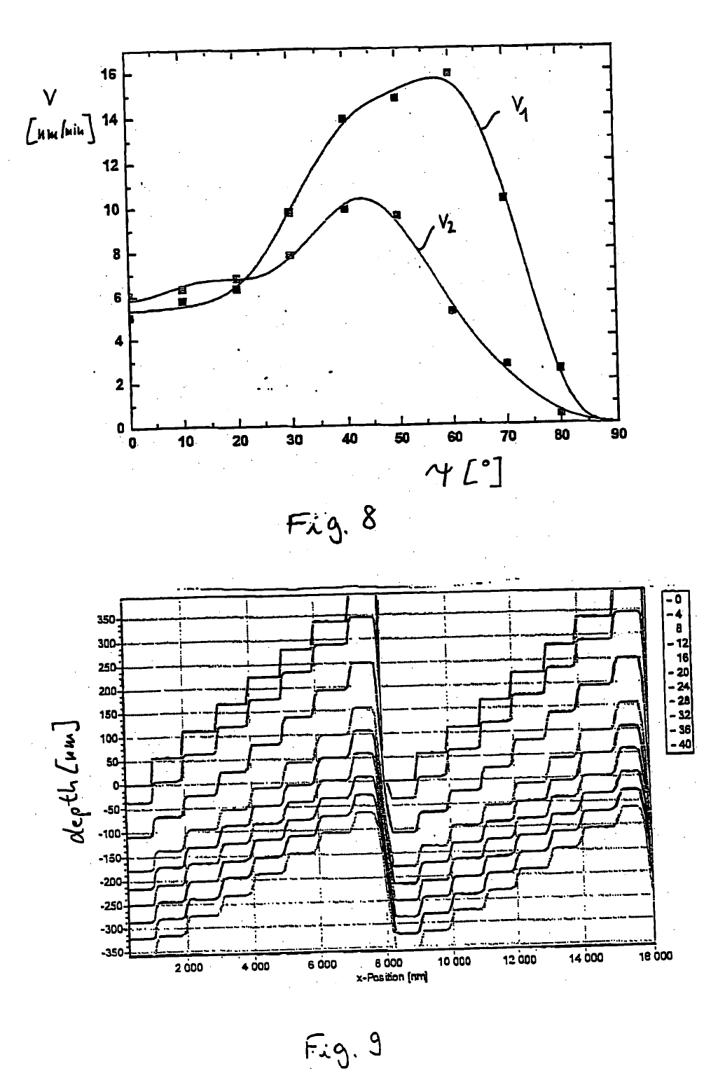

FIG. 9 shows a process simulation of an etching process of an 8-step-structure for manufacturing a diffractive optical element having such an 8-step-structure, wherein in this case auxiliary layer 66 consists of epoxy resin and substrate 62 consists of fused silica. Pure argon has been used as etching gas at an ion incidence angle of 35°. The uppermost line corresponds to a state of the manufacturing process, where a surface structure 54′ has been formed in auxiliary layer 66 corresponding to FIG. 7e), while the lowermost line shows a surface structure which corresponds to surface structure 54 of the final optical element 50 corresponding to FIG. 7f) which has been obtained after ion beam etching the compound of auxiliary 66 and substrate 62 for 40 min. The intermediate lines show intermediate states of the surface structure and the achieved depth of etching according to the time scale on the right hand side of FIG. 9.

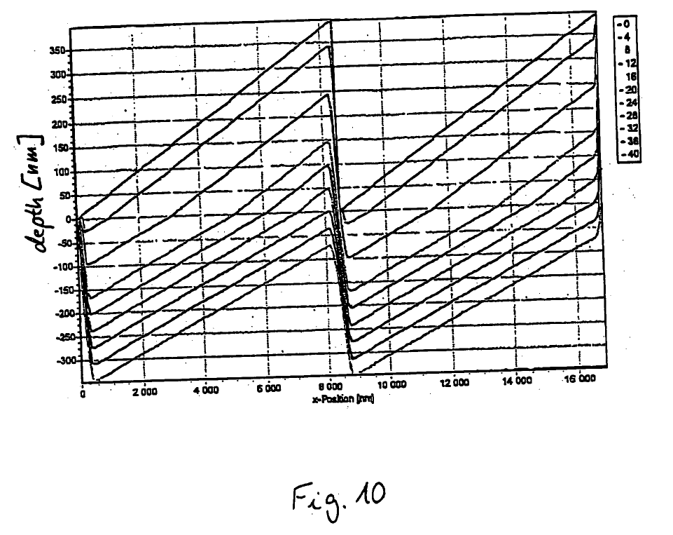

FIG. 10 shows in a similar way a process simulation of manufacturing an optical element (corresponding to optical element 50 in FIG. 7f)), a surface structure (corresponding to surface structure 54 in FIG. 7f)) of which is that of a blaze grating with fused silica used as substrate 62. Pure argon has been used as the etching gas at an ion incidence angle of 35°. Again, the uppermost line shows the surface structure at the beginning of the etching process (time zero), while the lowermost line shows the surface structure after 40 min etching time.

Further, when etching auxiliary layer 66 and subsequently substrate 62 in order to transfer surface structure 54′ to substrate 62 in order to obtain surface structure 54, the compound of auxiliary layer 66 and substrate 62 might be rotated during the etching process around an axis 74 perpendicular or approximately perpendicular to surface 65 of auxiliary layer 66. With this technique, the micro-roughness of the transferred surface structure 54′ is as minimal as possible because structural inhomogenities of the applied auxiliary layer 66 on the substrate 62 are averaged by the precision of the ion beam around the axis 74.

In order to account for alterations of the height of the transferred surface structure 54′ during the etching process the following measures are preferably taken into consideration. For example, master element 56 can be provided such that its surface structure 60 differs from the surface structure 54 to be obtained for the optical element 50 to be manufactured such that alterations during the etching process which are predictable are taken into account when generating surface structure 60 of master element 56. In this way, the etching process may be kept as easy as possible.

On the other hand, the surface structure 60 of master element 56 may be an identical, but negative copy of the optically effective structure 54, and the etching process is controlled as precisely as possible, for example by altering the gas mixture of the etching gas, by admixing reactive gases to the etching gas, by altering the ion incidence angle as mentioned above so that the surface structure 54′ of auxiliary layer 66 is transferred to optically effective structure 54 in unaltered or approximately unaltered fashion.

What is claimed is:

1. A method for manufacturing an optical element having at least one surface with an optically effective structure, from a substrate, comprising the steps of:
providing said substrate;
applying an auxiliary layer onto said substrate;
forming a surface structure on a surface of said auxiliary layer; and
ion beam etching said auxiliary layer such that said surface structure of said auxiliary layer is transferred to said substrate in order to obtain said optically effective structure of said optical element.

2. The method of claim 1, wherein said step of forming said surface structure is performed by means of a technique chosen from the group comprising photo-lithography, electron-beam lithography, ion-beam lithography, holography, mechanical partition, laser ablation, grinding, etching.

3. The method of claim 1, wherein said step of ion beam etching said auxiliary layer is performed such that said surface structure of said auxiliary layer is transferred to said substrate in approximately unaltered fashion.

4. The method of claim 1, wherein said step of ion beam etching said auxiliary layer comprises non-reactive ion beam etching said auxiliary layer.

5. The method of claim 1, wherein said step of providing said substrate comprises providing a fluoride crystal as said substrate.

6. The method of claim 5, wherein said fluoride crystal is chosen from the group comprising alkaline earth fluorides.

7. The method of claim 1, wherein said step of applying said auxiliary layer onto said substrate comprises applying a curable material as said auxiliary layer in liquid state.

8. The method of claim 7, wherein a liquid epoxy resin is used as said liquid curable material.

9. The method of claim 1, wherein said step of applying said auxiliary layer onto said substrate comprises spin-on depositing a curable material in liquid state onto said substrate.

10. The method of claim 1, wherein said step of applying said auxiliary layer onto said substrate comprises applying a curable material as said auxiliary layer in liquid state on said substrate, wherein said step of forming a surface structure on said surface of said auxiliary layer of material comprises providing a master element having a surface comprising said surface structure, pressing said master element onto said curable material so as to stamp said surface structure in said liquid curable material, curing said curable material, and separating said master element from said curable material after having been cured.

11. The method of claim 1, wherein said step of applying said auxiliary layer onto said substrate comprises applying a curable material onto said substrate in liquid state, curing said curable material, and wherein said step of forming said surface structure on said surface of said auxiliary layer comprises roughening said surface after said curable material has been cured, and chemically treating said surface so as to flatten said surface.

12. The method of claim 1, wherein said step of applying said auxiliary layer onto said substrate comprises applying a material as said auxiliary layer which allows a sufficiently homogeneous removal thereof by means of reactive ion etching.

13. The method of claim 1, wherein said step of applying said auxiliary layer onto said substrate comprises optically bonding said auxiliary layer onto said substrate.

14. The method of claim 13, wherein said step of applying said auxiliary layer onto said substrate comprises optically bonding a fused silica disc onto said substrate.

15. The method of claim 1, wherein said step of forming said surface structure on said surface of said auxiliary layer comprises removing material from said auxiliary layer, roughening said surface, and flattening said surface by means of chemical etching said surface.

16. The method of claim 1, wherein said step of applying said auxiliary layer onto said substrate comprises applying said auxiliary layer with a thickness significantly smaller than a thickness of said substrate.

17. The method of claim 1, wherein said step of ion beam etching said auxiliary layer comprises first reactive ion etching said auxiliary layer until a deepest site of said auxiliary layer approximately approaches said substrate, and then further non-reactive ion beam etching said auxiliary layer in order to transfer said surface structure of said auxiliary layer to said substrate.

18. The method of claim 1, wherein said step of applying an auxiliary layer onto said substrate comprises applying a photosensitive resist onto said substrate.

19. The method of claim 18, wherein said step of forming a surface structure on said auxiliary layer comprises exposing said photosensitive resist to an image of said surface structure, and developing said photosensitive resist.

20. The method of claim 1, wherein said step of applying an auxiliary layer onto said substrate comprises applying a photosensitive resist onto said substrate, and wherein said step of forming a surface structure on said auxiliary layer comprises generating a speckle pattern, exposing said photosensitive resist to said speckle pattern, and developing said photosensitive resist.

21. The method of claim 20, wherein said speckle pattern is generated by coherently illuminating a rough diffuser.

22. The method of claim 1, wherein said method is used for manufacturing an optical element having an optically effective surface structure, which optical element is comprised in the group comprising diffractive optical elements, refractive optical elements, scattering discs.

23. An optical element having at least one surface with an optically effective structure, wherein said optical element is manufactured from a substrate according to a method comprising the steps of:
providing said substrate;
applying an auxiliary layer onto said substrate;
forming a surface structure on a surface of said auxiliary layer of material; and
ion beam etching said auxiliary layer such that said surface structure of said auxiliary layer is transferred to said substrate in order to obtain said optically effective structure of said optical element.

24. The optical element of claim 23, wherein it is used in a projection illuminating system for semiconductor lithography.

25. A projection illuminating system, comprising at least one optical element having a surface with an optically effective structure, wherein said at least one optical element is manufactured from a substrate according to a method comprising the steps of:
providing said substrate;
applying an auxiliary layer onto said substrate;
forming a surface structure on a surface of said auxiliary layer of material; and
ion beam etching said auxiliary layer such that said surface structure of said auxiliary layer is transferred to said substrate in order to obtain said optically effective structure of said optical element.

26. A method for manufacturing an optical component having at least one surface with an optically effective structure, from a substrate, comprising the steps of:
providing a fluoride crystal as said substrate;
applying an auxiliary layer onto said substrate;
forming a surface structure on a surface of said auxiliary layer; and
non-reactive ion beam etching said auxiliary layer such that said surface structure of said auxiliary layer is transferred in approximately unaltered fashion to said substrate in order to obtain said optically effective structure of said optical element from said surface structure of said auxiliary layer.

27. A method for manufacturing an optical element having at least one surface with an optically effective structure, from a substrate, comprising the steps of:
providing said substrate;
applying a thin auxiliary layer onto said substrate by applying a curable material in liquid state onto said substrate;
forming a surface structure on a surface of said auxiliary layer by providing a master element having a surface comprising said surface structure in inverted form, pressing said master element onto said curable material so as to form said surface structure in said liquid curable material, curing said curable material, and separating said master element from said curable material after having been cured; and
removing said auxiliary layer by ion etching said auxiliary layer such that said surface structure of said auxiliary layer is transferred to said substrate.

28. The method of claim 27, wherein said step of forming said surface structure is performed by means of a technique chosen from the group comprising photo-lithography, electron-beam lithography, ion-beam lithography, holography, mechanical partition, laser ablation, grinding, etching.

29. The method of claim 27, wherein said step of providing said substrate comprises providing a substrate which is chosen from the group comprising materials transparent to light in a predetermined wavelength range.

30. The method of claim 29, wherein said substrate is chosen from the group of materials comprising glass, fused silica, silicon, germanium, silicon carbide, calcium fluoride, magnesium fluoride, zinc selenide.

31. The method of claim 27, wherein said step of providing said substrate comprises providing a substrate which is chosen from the group comprising materials reflective to light in a predetermined wavelength range.

32. The method of claim 31, wherein said substrate is chosen from the group of materials comprising silver, gold, aluminum, ruthenium.

33. The method of claim 27, wherein said step of providing said substrate comprises providing a substrate which is chosen from the group comprising heat conducting materials.

34. The method of claim 27, wherein said substrate is chosen from the group comprising materials having a high mechanical hardness.

35. The method of claim 27, wherein said step of applying said curable material onto said substrate comprises using a curable material having a viscosity≦150 mm²/s at room temperature.

36. The method of claim 27, wherein an epoxy resin with low viscosity in liquid state is used as said curable material.

37. The method of claim 27, wherein said step of applying said auxiliary layer onto said substrate comprises applying said auxiliary layer with a thickness in the range of about 10 nm to about 1000 nm.

38. The method of claim 27, wherein said step of pressing said master element onto said curable material comprises pressing said master element onto said curable material with a pressure in a range of about 0.1 to about 5 bar.

39. The method of claim 27, wherein said step of curing said curable material comprises thermally curing at an elevated temperature.

40. The method of claim 27, wherein said step of removing said auxiliary layer by ion etching comprises an ion etching process chosen from the group comprising shape-maintaining ion beam etching, reactive ion beam etching, reactive ion etching and combinations thereof.

41. The method of claim 27, wherein said step of providing said master element comprises providing said master element with a surface structure that accounts for alterations of said surface structure during said step of removing said auxiliary layer so as to obtain said desired optically effective structure after etching.

42. The method of claim 27, wherein said step of removing said auxiliary layer by ion etching comprises controlling said ion etching such that said surface structure of said auxiliary layer is transferred to said substrate in approximately unaltered fashion.

43. The method of claim 27, wherein said step of removing said auxiliary layer comprises controlling a first etch rate for said auxiliary layer with respect to a second etch rate for said substrate.

44. The method of claim 43, wherein said controlling said first etch rate with respect to said second etch rate comprises admixing at least one reactive gas for etching said auxiliary layer and admixing at least one reactive gas for etching said substrate.

45. The method of claim 27, wherein said step of removing said auxiliary layer by ion etching comprises an ion etching process chosen from the group comprising shape-maintaining ion beam etching, reactive ion beam etching, reactive ion etching and combinations thereof, and wherein an angle of incidence of ions is adjusted such that said transferring of said surface structure of said auxiliary layer to said substrate is optimally shape-maintaining.

46. The method of claim 45, wherein said angle of incidence of ions is changed during said ion etching process.

47. The method of claim 27, wherein said step of providing said master element comprises providing said master element with a surface structure which is a negative copy of said optically effective structure to be obtained.

48. The method of claim 27, wherein said step of removing said auxiliary layer by ion etching further comprises rotating said substrate and said auxiliary layer during said ion etching around an axis perpendicular to said surface of said auxiliary layer.

49. The method of claim 27, wherein said method is used for manufacturing an optical element having at least one optically effective surface structure, which optical element is comprised in the group comprising diffractive optical elements, refractive optical elements, scattering discs.

50. A method for manufacturing an optical element having at least one surface with an optically effective structure, from a substrate, comprising the steps of:
providing said substrate;
applying a thin auxiliary layer onto said substrate which auxiliary layer has a thickness in the range of about 10 nm to about 10000 nm, by applying a curable material in liquid state onto said substrate;
forming a surface structure on a surface of said auxiliary layer of material by providing a master element having a surface comprising said surface structure, pressing said master element onto said curable material so as to form said surface structure in said liquid curable material, curing said curable material, and separating said master element from said curable material after having been cured; and
removing said auxiliary layer by ion etching said auxiliary layer such that said surface structure of said auxiliary layer is transferred to said substrate.

51. An optical element having at least one surface with an optically effective structure, wherein said optical element is manufactured from a substrate according to a method comprising the steps of:
providing said substrate;
applying a thin auxiliary layer onto said substrate by applying a curable material in liquid state onto said substrate;
forming a surface structure on a surface of said auxiliary layer by providing a master element having a surface comprising said surface structure in inverted form, pressing said master element onto said curable material so as to form said surface structure in said liquid curable material, curing said curable material, and separating said master element from said curable material after having been cured; and
removing said auxiliary layer by ion etching said auxiliary layer such that said surface structure of said auxiliary layer is transferred to said substrate.

52. The optical element of claim 51, wherein said optical element is used in a projection illuminating system for microlithography.

53. The optical element of claim 51, wherein said optical element is used in microlithography in a wavelength range <248 nm.

54. A projection illuminating system, comprising at least one optical element having at least one surface with an optically effective structure, wherein said at least one optical element is manufactured from a substrate according to a method comprising the steps of:
providing said substrate;
applying a thin auxiliary layer onto said substrate by applying a curable material in liquid state onto said substrate;
forming a surface structure on a surface of said auxiliary layer by providing a master element having a surface comprising said surface structure in inverted form, pressing said master element onto said curable material so as to form said surface structure in said liquid curable material, curing said curable material, and separating said master element from said curable material after having been cured; and
removing said auxiliary layer of material by ion etching said auxiliary layer such that said surface structure of said auxiliary layer is transferred to said substrate.
